(19) United States
(12) Patent Application Publication
(10) Pub. No.: US 2014/0239962 A1
(43) Pub. Date: Aug. 28, 2014

(54) FUEL CELL INSPECTION METHOD AND INSPECTION DEVICE

(71) Applicants: Tohru Oda, Toyota-shi (JP); Atsushi Yamamoto, Toyota-shi (JP)

(72) Inventors: Tohru Oda, Toyota-shi (JP); Atsushi Yamamoto, Toyota-shi (JP)

(73) Assignee: TOYOTA JIDOSHA KABUSHIKI KAISHA, Toyota-shi (JP)

(21) Appl. No.: 14/342,114

(22) PCT Filed: Aug. 27, 2012
(86) PCT No.: PCT/IB2012/001636

§ 371 Date: Feb. 28, 2014

(30) Foreign Application Priority Data
Sep. 5, 2011 (JP) 2011-192506

(51) Int. Cl. H01M 8/04; G01R 31/36

(52) U.S. Cl. CPC H01M 8/04582; G01R 31/3627
USPC 324/426

(57) ABSTRACT

A fuel cell inspection method includes: applying DC voltage of a first voltage value, in a first period, to a power generation element that has an electrolyte membrane, an anode-side catalyst layer disposed on one side of the electrolyte membrane, and a cathode-side catalyst layer disposed on the other side of the electrolyte membrane; and applying, to the power generation element, DC voltage of a second voltage value that is lower than the first voltage value, in a second period after the first period; and detecting a value of current flowing in the power generation element.

### BACKGROUND OF THE INVENTION

1. Field of the Invention

The invention relates to a fuel cell inspection method and inspection device.

2. Description of Related Art

Fuel cells, for instance polymer electrolyte fuel cells, directly convert chemical energy in substances to electric energy as a result of an electrochemical reaction elicited through supply of reaction gases (fuel gas and oxidant gas) to a membrane electrode assembly (hereafter also referred to as “MEA”) that is produced by sandwiching an electrolyte membrane between a pair of electrodes (anode and cathode).

Studies have been conducted on, for instance, achieving thinner MEAs with a view to enhancing proton conductivity. Thinner MEAs give rise to concerns that include greater likelihood of occurrence of impaired gas and electron shielding functionality that is required from the MEA, on account of, for instance, foreign matter that intrudes into the interface of the MEA with a gas diffusion electrode, and due to scratches and the like during handling. The foregoing occurrences, which translate into poorer fuel cell performance, can be determined through inspection of the MEA for electric leaks and gas leaks (hereafter also referred to as “leaks”). In a conventional method (for instance, Japanese Patent Application Publication No. 2006-86130 (JP 2006-86130 A)), the occurrence of leaks in an MEA is inspected on the basis of a steady-state current value that is detected from the MEA, upon application of constant DC voltage to the MEA.

Although the above inspection method allows inspecting leaks in MEAs, the method is still problematic in that it takes time for the current that flows upon application of DC voltage to the MEA to reach a steady-state current value. This makes for a longer inspection time of the fuel cell.

### SUMMARY OF THE INVENTION

The invention shortens the inspection time of a fuel cell.

A first aspect of the invention relates to a fuel cell inspection method that includes: applying DC voltage of a first voltage value, in a first period, to a power generation element; applying, to the power generation element, DC voltage of a second voltage value that is lower than the first voltage value, in a second period after the first period, and detecting a value of current flowing in the power generation element. The power generation element has an electrolyte membrane, an anode-side catalyst layer disposed on one side of the electrolyte membrane, and a cathode-side catalyst layer disposed on the other side of the electrolyte membrane.

The fuel cell inspection method involves applying DC voltage of a first voltage value, in a first period, to a power generation element; applying, to the power generation element, DC voltage of a second voltage value that is lower than the first voltage value, in a second period that follows the first period, and detecting a value of current flowing in the power generation element. As a result, formation of an electric double layer in the power generation element is complete at the time where the current value is detected. This allows inspecting the occurrence or absence of leaks in the power generation element. Accordingly, the fuel cell inspection method allows inspecting a power generation element in a short time.

The inspection method may include: comparing the detected current value with a predetermined threshold value.

In the fuel cell inspection method, it is determined whether a leak has occurred in the power generation element by comparing the detected current value with a threshold value set beforehand. Therefore, the occurrence or absence of leaks in the power generation element can be determined in a simpler manner if a threshold value is set beforehand.

A length of the first period may range from 0.5 seconds to 2.5 seconds.

In the fuel cell inspection method, the current that flows upon application of DC voltage to the power generation element can be detected at a time where the current takes on a steady-state current value, the inspection time of the occurrence or absence of leaks in the power generation element can be shortened, and high-precision inspection, with few reading errors, becomes possible.

A value obtained by multiplying a length of the first period by a coefficient that is calculated by dividing the first voltage value by the second voltage value may range from 0.4 to 4.0.

In the fuel cell inspection method, the current that flows upon application of DC voltage to the power generation element can be detected at a time where the current takes on a steady-state current value, the inspection time of the occurrence or absence of leaks in the power generation element can be shortened, and high-precision inspection, with few reading errors, becomes possible.

The current value may be detected at a time where a predetermined time has elapsed from a start of the second period.

The fuel cell inspection method precludes detection of a current value for which formation of an electric double layer is not complete on account of changeover, from the first voltage value to the second voltage value, of the DC voltage that is applied to the power generation element. High-precision inspection, with few reading errors, becomes possible thereby.

The predetermined time may range from 1 second to 5 seconds.

The fuel cell inspection method precludes detection of a current value for which formation of an electric double layer is not complete on account of changeover of the DC voltage that is applied to the power generation element from the first voltage value to the second voltage value. If detection of the current value is performed within 5 seconds from the start of the second period, then the current value is detected quickly, after formation of the electric double layer in the power generation element is complete. Accordingly, the fuel cell inspection method allows inspecting a power generation element in a shorter time and with high precision.

The second voltage value may be 0.5 volts or less.

In the fuel cell inspection method, the value of the voltage that is applied to the power generation element and the detected current value stand in a substantial proportional relationship, and hence variability across samples of the power generation element can be reduced.

The second period may start at the same time when the first period ends.

In the fuel cell inspection method, the inspection time of the power generation element can be shortened to the utmost, in that there is no additional process between the first period and the second period.

A second aspect of the invention relates to a fuel cell inspection device that has a voltage application unit that applies DC voltage of a first voltage value, in a first period, and that applies DC voltage of a second voltage value that is lower than the first voltage value, in a second period after the first period, to a power generation element; and a detection unit that detects a value of current flowing in the power generation element, in the second period. The power generation element has an electrolyte membrane, an anode-side catalyst layer disposed on one side of the electrolyte membrane, and a cathode-side catalyst layer disposed on the other side of the electrolyte membrane.

The invention can be realized in various ways, in the form of, for instance, a fuel cell and a fuel cell inspection method and manufacturing method, a fuel cell stack, a fuel cell stack inspection method and manufacturing method, a moving body provided with a fuel cell, and an inspection method and manufacturing method of a moving body provided with a fuel cell.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is an explanatory diagram illustrating schematically the configuration of a fuel cell 100 in an example of the invention;

FIG. 2 is a flowchart illustrating the flow of inspection of an MEA 110 in an example of the invention;

FIG. 3 is an explanatory diagram illustrating schematically the way in which the MEA 110 is inspected in an example of the invention;

FIG. 4 is an explanatory diagram illustrating an example of a current value that is detected upon application of DC voltage to the MEA 110 in an example of the invention;

FIG. 5 is an explanatory diagram illustrating a relationship between detected current values at various times in an inspection method in a comparative example;

FIG. 6 is an explanatory diagram illustrating a deviation amount that is calculated on the basis of detection time and a current value detected from the MEA 110 to which voltage is applied, in an inspection method in an example of the invention;

FIGS. 7A and 7B are explanatory diagrams illustrating a deviation amount that is calculated on the basis of detection time and a current value detected from the MEA 110 to which voltage is applied, in an inspection method in an example of the invention; and

FIG. 8 is an explanatory diagram illustrating a voltage value that is applied to the MEA 110 and a detected current value in an inspection method of an example of the invention.

### DETAILED DESCRIPTION OF EMBODIMENTS

An embodiment of the invention will be explained next based on examples, in the following order:

A. Example

A-1. Configuration of a Fuel Cell

A-2. Inspection Process of a Power Generation Element

A-3. Precision Evaluation

B. Variations

A. Example:

A-1. Configuration of a Fuel Cell

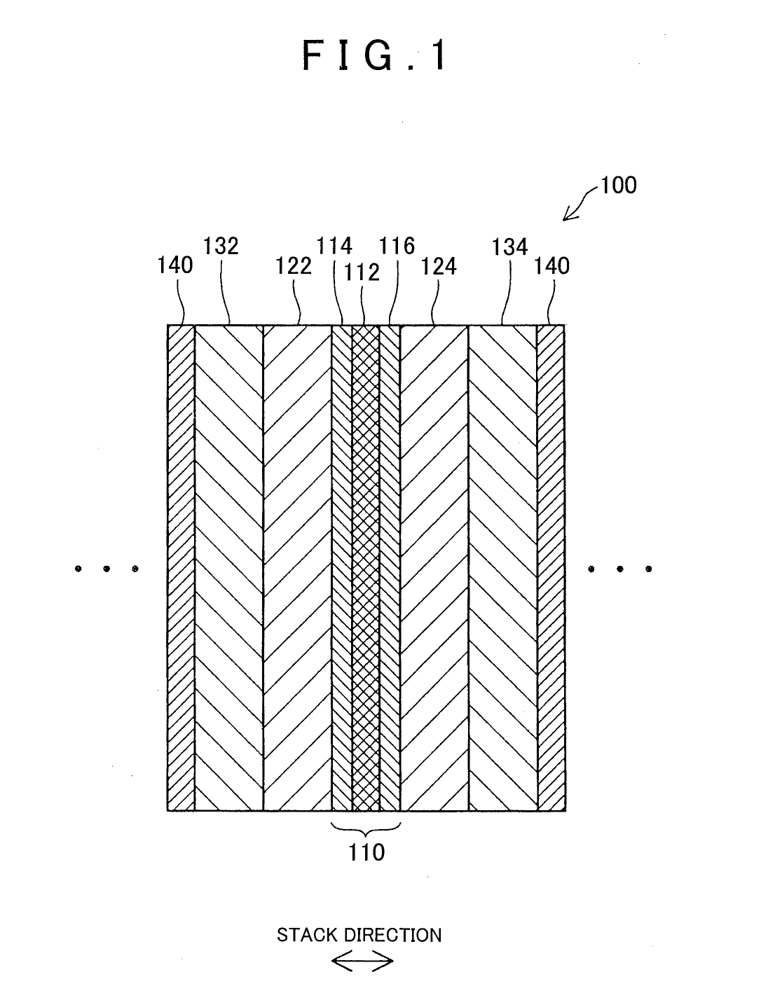

FIG. 1 is an explanatory diagram illustrating schematically the configuration of a fuel cell 100 in an example of the invention. The fuel cell 100 of the example is a comparatively small polymer electrolyte fuel cell having excellent power generation efficiency. The fuel cell 100 has a stacked structure wherein a separator 140, a cathode-side gas flow path layer 132, a cathode-side diffusion layer 122, a MEA 110, an anode-side diffusion layer 124 and an anode-side gas flow path layer 134 are stacked, in the form of a plurality of layers, and are fastened. The MEA 110 can be regarded as the power generation element of the invention.

As illustrated in FIG. 1, the MEA 110 is made up of an electrolyte membrane 112, an anode 116 disposed on one side of the electrolyte membrane 112, and a cathode 114 disposed on the other side of the electrolyte membrane 112. The anode 116 is in contact with the anode-side diffusion layer 124, on the opposite side to the electrolyte membrane 112. The cathode 114 is in contact with the cathode-side diffusion layer 122, on the opposite side to the electrolyte membrane 112. The anode-side gas flow path layer 134 is disposed between the anode-side diffusion layer 124 and the separator 140, and the cathode-side gas flow path layer 132 is disposed between the cathode-side diffusion layer 122 and the separator 140. For the sake of an easier comprehension of the configuration of the fuel cell 100, FIG. 1 illustrates only one cell made up of one MEA 110, other cells having been omitted from the figure.

The electrolyte membrane 112 is an ion-exchange membrane formed of a fluororesin material or a hydrocarbon resin material, and has good proton conductivity when in a wet state. The anode 116 and the cathode 114 are layers that provide a catalyst that promotes electrode reactions, and are formed of materials that have an electrolyte and carbon that supports, for instance, platinum. The anode-side diffusion layer 124 and the cathode-side diffusion layer 122 are layers through which respective reaction gases (fuel gas and oxidant gas), which are used in the electrode reactions, diffuse in a surface direction (direction substantially perpendicular to the stack direction (FIG. 1) of the fuel cell 100). The anode-side diffusion layer 124 and cathode-side diffusion layer 122 are formed, for instance, of carbon cloth or carbon paper. In the example, the diffusion layers are subjected to a hydrophobizing treatment using a PTFE resin.

The separator 140 is formed of a conductive material that is compact and gas-impervious, for instance compression-molded compact carbon, a metal, or a conductive resin. The anode-side gas flow path layer 134 and the cathode-side gas flow path layer 132 are layers that function as reaction gas flow paths through which the reaction gases flow along the surface direction of the fuel cell 100. The anode-side gas flow path layer 134 and the cathode-side gas flow path layer 132 are formed, for instance, of a conductive porous material such as a metallic porous body, a carbon porous body or the like. In the example, the surface of the anode-side gas flow path layer 134 and of the cathode-side gas flow path layer 132 are subjected to a hydrophilizing treatment.

Although not shown in FIG. 1, every fuel cell 100 has a fuel gas supply manifold, a fuel gas discharge manifold, an oxidant gas supply manifold, and an oxidant gas discharge manifold that run through the fuel cell 100 in the stack direction. The fuel gas that is supplied to the fuel cell 100 is distributed to the anode-side gas flow path layer 134 of each cell, via the fuel gas supply manifold, diffuses through the anode-side diffusion layer 124, and is supplied to the anode-side of the MEA 110, to be used in the electrochemical reaction in the MEA 110. The fuel gas that is not used in the reaction is discharged out of the fuel cell 100 via the fuel gas discharge manifold. The oxidant gas that is supplied to the fuel cell 100 is distributed to the cathode-side gas flow path layer 132 of each cell via the oxidant gas supply manifold, diffuses through the cathode-side diffusion layer 122, and is supplied to the cathode-side of the MEA 110, to be used in the electrochemical reaction in the MEA 110. The oxidant gas that is not used in the reaction is discharged out of the fuel cell 100 via the oxidant gas discharge manifold. For instance, hydrogen gas is used as the fuel gas and air is used as the oxidant gas.

A-2. Inspection Process of the Power Generation Element

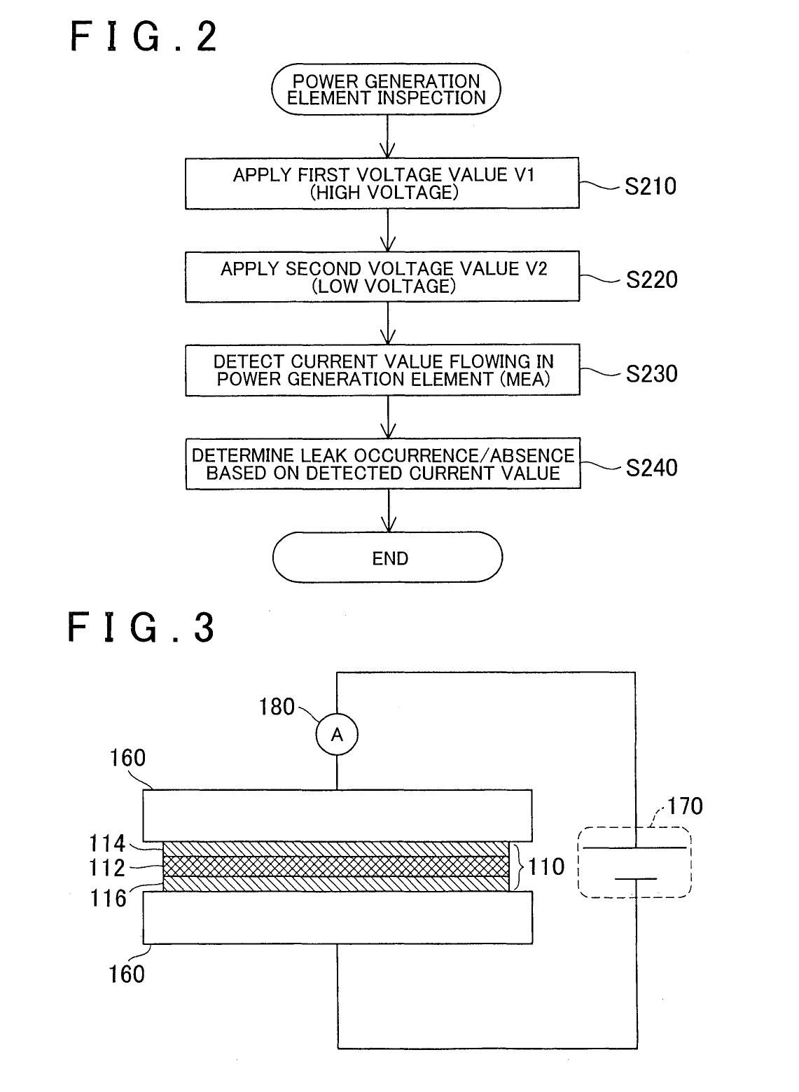

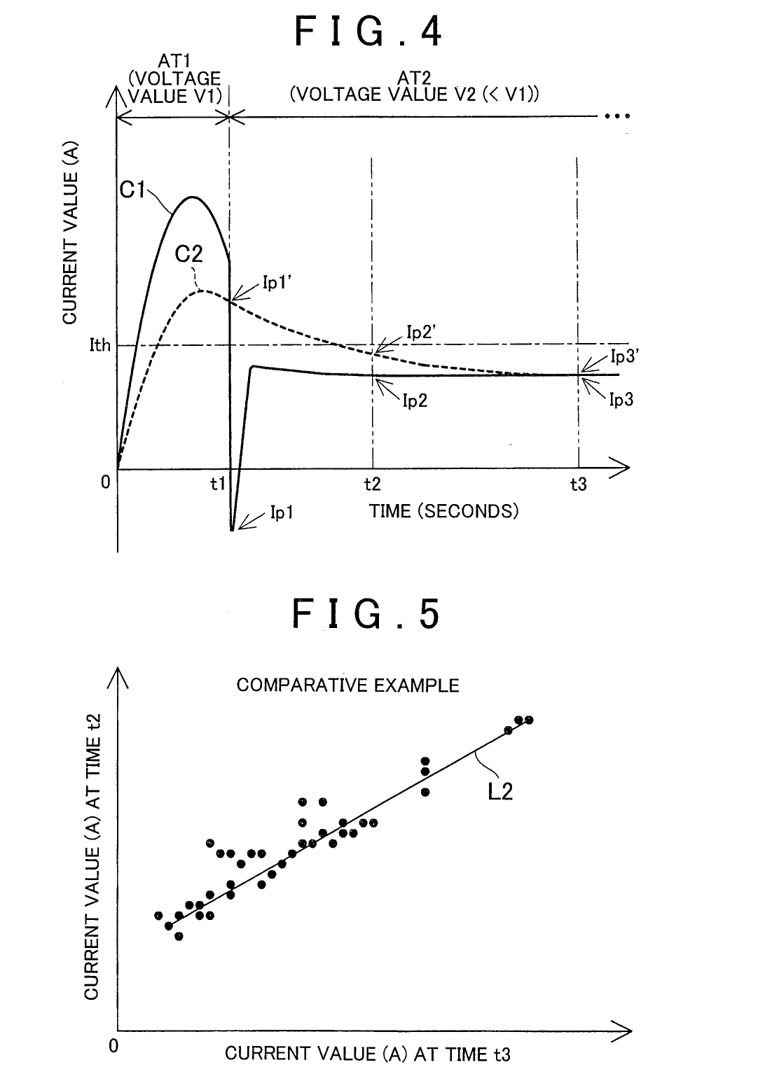

FIG. 2 is a flowchart of the flow of inspection of the MEA 110 in an example of the invention. FIG. 3 is an explanatory diagram illustrating schematically the way in which the MEA 110 is inspected in an example of the invention. FIG. 4 is an explanatory diagram illustrating an example of a current value that is detected upon application of DC voltage to the MEA 110 in an example of the invention. Inspection of the MEA 110 in the example involves applying DC voltage to the MEA 110, detecting current flowing in the MEA 110 upon voltage application, and determining the occurrence or absence of electron leaks and gas leaks (hereafter also referred to as “leaks”) in the MEA 110 on the basis of the detected current value.

Firstly, DC voltage is applied to the MEA 110 (step S210 in FIG. 2). As illustrated in FIG. 3, the MEA 110 is sandwiched between a pair of metal plates 160, and fastened. The pair of metal plates 160 is connected to a DC power source 170. An ammeter 180 is provided between the DC power source 170 and the pair of metal plates 160. The value of current that flows in the MEA 110 can be thus detected.

A current curve C1 in FIG. 4 denotes an example of a current measurement result in the inspection method of the example. A current curve C2 in FIG. 4 denotes an example of a current measurement result in the inspection method in a comparative example described below. The abscissa axis represents time and the ordinate axis represents the current value. As illustrated in FIG. 4, a first voltage value V1 is applied to the MEA 110 in a first period AT1 that spans from the start of application of voltage to the MEA 110 up to time t1. Upon application of a DC voltage in the first period AT1, an electric double layer begins to form in the MEA 110, and hence the value of current flowing in the MEA 110 rises gradually, as denoted by the current curve C1, and then the current value decreases after having reached a certain peak. The first voltage value V1 in the inspection method of the example is a constant voltage value of 0.2 V (volts), and time t1 is 1 second, i.e. the length of the first period AT1 is 1 second.

Then, a second voltage value V2 is applied to the MEA 110 (step S220 in FIG. 2). As illustrated in FIG. 4, the second voltage value V2, which is lower than the first voltage value V1, is applied to the MEA 110 in a second period AT2 from time t1 onwards, i.e. starting at the same time that the first period AT1 ends. Upon switching from the first period AT1 to the second period AT2, the DC voltage that is applied to the MEA 110 changes over to the second voltage value V2 that is lower than the first voltage value V1, and hence part of the electric double layer that has begun to form in the MEA 110 in the first period AT1 is discharged. As a result, a current value Ip1 at time t1 of changeover in the applied voltage takes on a negative current value. Formation of the electric double layer in the MEA 110 on account of the second voltage value V2 is completed a while after discharge is over, and the current flowing in the MEA 110 becomes a constant steady-state current. In the inspection method of the example, the second voltage value V2 is a constant voltage value of 0.1 V.

Then, The value of current flowing in the MEA 110 is detected (step S230 in FIG. 2). As illustrated in FIG. 4, a current value Ip2 is detected at time t2, at which there is detected a current value for determining the occurrence or absence of-leaks in the MEA 110, a while after time t1. In the inspection method of the example, formation of the electric double layer in the MEA 110 is already complete by time t2. From time t2 onwards, therefore, the value of current flowing in the MEA 110 is substantially a constant steady-state current value. If time t2 is small, that is, the value of current flowing in the MEA 110 is detected when not much time has passed from the start time t1 of the second period AT2, a current value that is not a steady-state current may be detected in some instances because formation of the electric double layer in the MEA 110 is not complete. Preferably, therefore, time t2 is 1 or more seconds later than the start time t1 of the second period AT2. To detect the value of current flowing in the MEA 110 it is sufficient for the electric double layer of the MEA 110 to have formed completely. Accordingly, time t2 is preferably set to within 5 seconds from the start time t1 of the second period AT2, in order to shorten the inspection time of the MEA 110. In the inspection method of the example, the time t2 is set to 4 seconds, and the current value Ip2 from the MEA 110 is detected when 3 seconds have elapsed from the start time t1 of the second period AT2.

Next, the detected current value Ip2 and a predetermined threshold value Ith are compared to determine the occurrence or absence of leaks in the MEA 110 (step S240 in FIG. 2). A leak current is generated when a leak occurs in the MEA 110. As a result, the detected current value of the steady-state current becomes higher than that in the MEA 110 when no leak has occurred. In consequence, the threshold value Ith is set, on the basis of an experimental value, to a value that allows determining the occurrence or absence of a leak in the MEA 110. If the current value Ip2 is higher than the threshold value Ith, it is determined that a leak has occurred in the MEA 110. On the other hand, if the current value Ip2 is lower than the threshold value Ith, it is determined that no leak has occurred in the MEA 110.

As described above, in the inspection method of the example, DC voltage of the first voltage value V1 is applied to the MEA 110 in the first period AT1, DC voltage of the second voltage value V2 lower than the first voltage value V1 is applied during the second period AT2 that is subsequent to the first period AT1, and the value Ip2 of current that flows in the MEA 110 is detected at time t2. As a result, the MEA 110 can be inspected in a short time, as explained below.

In an inspection method according to a comparative example, the second voltage value V2 is applied to the MEA 110 both in the first period AT1 and the second period AT2. The second voltage value V2 is the same as in the above-described example, i.e. a voltage of 0.1 V. In the inspection method of the comparative example, the value of current flowing in the MEA 110 rises gradually upon application of DC voltage, as denoted by the current curve C2 in FIG. 4. The current value decreases then gradually after a certain peak is reached, and takes on a steady-state current value after a while. Therefore, the value of current Ip1′ flowing in the MEA 110 at time t1 is unaffected by discharge on account of changeover in the applied voltage, and does not become thus a negative current value. In the inspection method of the comparative example, the applied voltage in the first period AT1 is lower than that in the example. Therefore, formation of the electric double layer in the MEA 110 requires more time than in the example, and it takes more time for the current value to take on a constant steady-state current value. In the inspection method of the comparative example, as a result, the value Ip2′ of current flowing in the MEA 110 at time t2 is not a steady-state current value; instead, a value Ip3′ of current flowing in the MEA 110 at time t3, at which further time has elapsed since time t2, is herein the steady-state current value. Accordingly, the current value Ip2′ is a larger current value than the current value Ip3′. As indicated by the current curve C1 in FIG. 4, the current value Ip3 at time t3 in the example is a steady-state current value that is substantially identical to the current value Ip2 at the time t2 in the example. Time t3 in the inspection method of the comparative example is 60 seconds.

FIG. 5 is an explanatory diagram illustrating the relationship between detected current values at various times in the inspection method of the comparative example. The abscissa axis in FIG. 5 is the current value Ip3′ detected at time t3, and the ordinate axis is the current value Ip2′ detected at time t2. FIG. 5 illustrates the relationship between the current value Ip2′ detected at time t2 and the current value Ip3′ detected at time t3, upon application of DC voltage of the second voltage value V2 in MEAs 110 of a plurality of samples. FIG. 5 illustrates an approximation straight line L2 that is calculated from a plurality of data of the current value Ip2′ and the current value Ip3′. The value corresponding to 3a in the frequency distribution as calculated based on the current value difference between the current value Ip2′ and the current value Ip3′ in the inspection method of the comparative example is 8.7 mA (milliamperes), which is greater than the value in the below-described example. That is, the difference between the current value Ip2′ and the current value Ip3′ is large. As a result, it becomes difficult to determine, with high precision, the occurrence or absence of leaks in the MEA 110 on the basis of a comparison between the threshold value Ith a the current value Ip2′ as detected, at time t2, in the inspection method of the comparative example.

In the inspection method of the fuel cell 100 of the example, by contrast, formation of an electric double layer in the MEA 110 is complete by time t2, and hence it becomes possible to inspect the occurrence or absence of leaks in the MEA 110. Accordingly, the inspection method of the fuel cell 100 of the example allows inspecting the MEA 110 in a short time.

In the inspection method of the fuel cell 100 of the example the occurrence or absence of leaks in the MEA 110 is determined by comparing the predetermined threshold value Ith with the current value Ip2 detected at time t2. Accordingly, the occurrence or absence of leaks in the MEA 110 can be determined in a simpler manner if the threshold value Ith is set beforehand. In consequence, the inspection method of the fuel cell 100 of the example allows inspecting the MEA 110 in a short time and in a simple manner.

In the inspection method of the fuel cell 100 of the example, preferably, the current value Ip2 is detected at a point in time where 1 or more seconds have elapsed since the start time t1 of the second period AT2, in order to avoid detection of a current value that does not yield a steady-state current value. Preferably, the current value Ip2 is detected within 5 seconds from the start time t1 of the second period AT2, in order to shorten the inspection time of the MEA 110. Performing detection of the current value

Ip2 at a point in time where 1 or more seconds have elapsed since the start time t1 of the second period AT2 precludes detection of a current value for which formation of the electric double layer is not complete, accompanying the changeover, from the first voltage value V1 to the second voltage value V2, of the DC voltage that is applied to the MEA 110. High-precision inspection with few reading errors becomes possible as a result. When detection of the current value Ip2 is performed within 5 seconds from the start time t1 of the second period AT2, the current value is detected quickly, after formation of the electric double layer in the MEA 110 is complete, and hence the inspection time of the MEA 110 can be shortened. Accordingly, the inspection method of the fuel cell 100 of the example allows inspecting the MEA 110 in a shorter time and with high precision.

In the inspection method of the fuel cell 100 of the example, the second period AT2 begins at the same time that the first period AT1 ends. Accordingly, the inspection time of the MEA 110 can be shortened to the utmost, since there is no additional process between the first period All and the second period AT2. Accordingly, the inspection method of the fuel cell 100 of the example allows inspecting the MEA 110 in a shorter time.

A-3. Precision Evaluation:

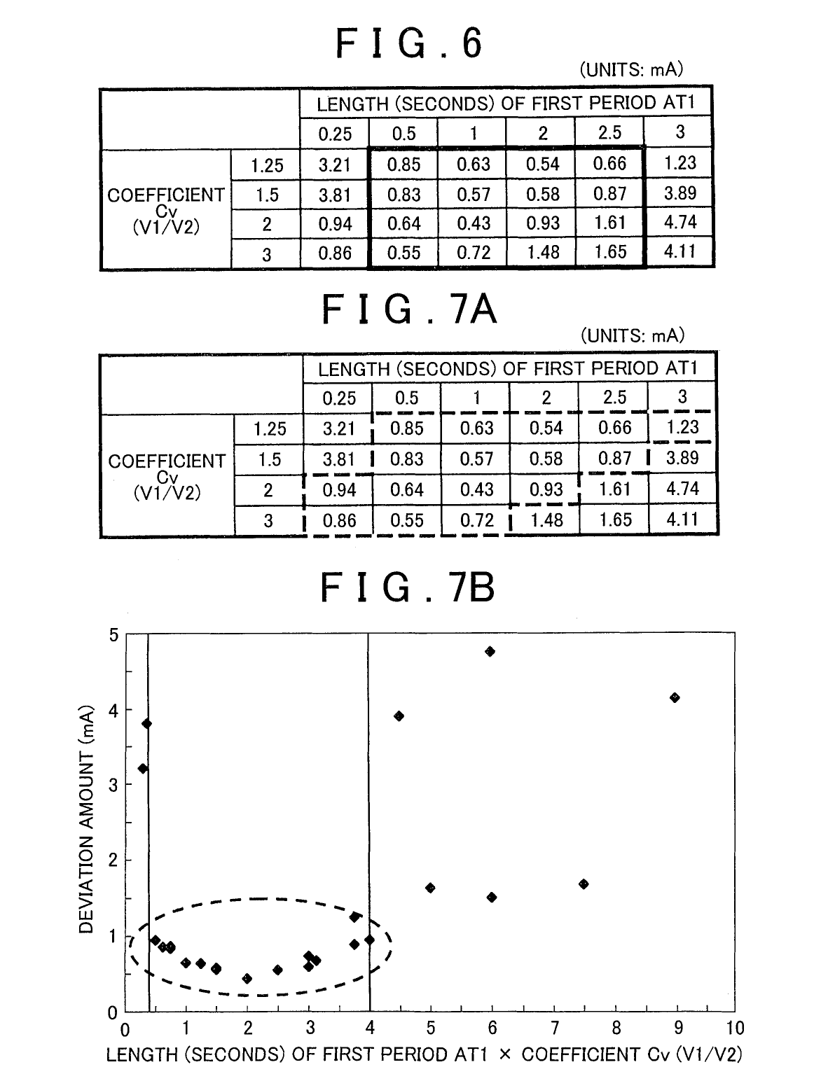

FIG. 6 and FIGS. 7A and 7B are explanatory diagrams illustrating a deviation amount that is calculated on the basis of detection time and a current value detected from the MEA 110 to which voltage is applied, in the inspection method of the example of the invention. FIG. 6 illustrates a deviation amount calculated from the current value Ip2 and the current value Ip3, for conditions of the length of the first period AT1 in which the first voltage value V1 is applied to the MEA 110, and a coefficient Cv that results from dividing the first voltage value VI by the second voltage value V2. This deviation amount is a value that corresponds to 3σ in a frequency distribution calculated from the current value difference obtained by subtracting the current value Ip3 from the current value Ip2.

As FIG. 6 shows, the deviation amount is large in some instances, depending on the value of the coefficient Cv, in case of excessively long or short length of the first period AT1 in which the first voltage value VI is applied to the MEA 110. For instance, the deviation amount is 3.81 mA when the length of the first period AT1 is 0.25 seconds, the first voltage value V1 is 0.3 V and the second voltage value V2 is 0.2 V (i.e. when the coefficient Cv is 1.5). The deviation amount is 4.74 mA when the length of the first period AT1 is 3 seconds, the first voltage value V1 is 0.2 V and the second voltage value V2 is 0.1 V (i.e. when the coefficient Cv is 2). Accordingly, the length of the first period AT1 in which the first voltage value V1 is applied ranges preferably from 0.5 seconds to 2.5 seconds, as in the bold-line enclosure of FIG. 6. In the above-described example, the deviation amount is 0.43 mA when the length of the first period AT1 is 1 second, the first voltage value V1 is 0.2 V and the second voltage value V2 is 0.1 V (i.e. when the coefficient Cv is 2.0).

In FIG. 7A, the deviation amount is identical to that of FIG. 6, but the portion of the bold line and the portion of a below-described dotted line are different. FIG. 7B illustrates the relationship between a numerical value obtained by multiplying the length of the first period AT1 by the coefficient Cv, and the deviation amount calculated from the current value Ip2 and the current value Ip3. The portion enclosed by the dotted line in FIG. 7A is the same range as enclosed by the dotted line in FIG. 7B. The solid lines in FIG. 7B denote the numerical values of 0.4 and 4 obtained by multiplying the length of the first period AT1 by the coefficient Cv. As FIG. 7B shows, the deviation amount is large in instances where the value obtained by multiplying the coefficient Cv and the length of the first period AT1 in which the first voltage value V1 is applied to the MEA 110 is a small value or a large value. For instance, the value obtained by multiplying the length of the first period AT1 by the coefficient Cv is 0.3125, and the deviation amount is 3.21 mA, when the length of the first period AT1 is 0.25 seconds, the first voltage value V1 is 0.25 V and the second voltage value V2 is 0.2 V (i.e. when the coefficient Cv is 1.25). The value obtained by multiplying the length of the first period AT1 by the coefficient Cv is 9, and the deviation amount is 4.11 mA, when the length of the first period AT1 is 3 seconds, the first voltage value V1 is 0.3 V and the second voltage value V2 is 0.1 V (i.e. when the coefficient Cv is 3). Accordingly, the value obtained by multiplying the length of the first period AT1. by the coefficient Cv ranges preferably from 0.4 and 4.0, as in the enclosure of the dotted line in FIG. 7B. In the above-described example, the value obtained by multiplying the length of the first period AT1 by the coefficient Cv is 2.0.

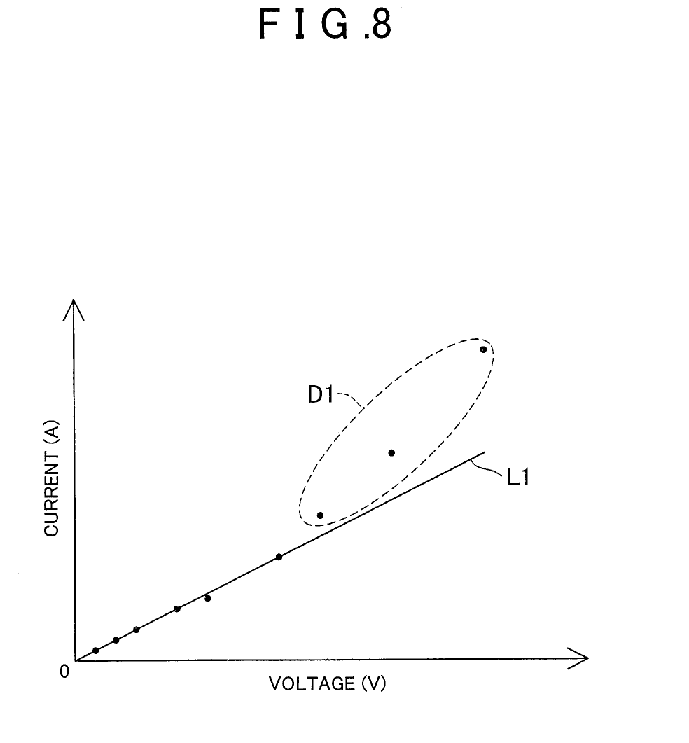

FIG. 8 is an explanatory diagram illustrating a voltage value that is applied to the MEA 110 and a detected current value in an inspection method of an example of the invention. FIG. 8 illustrates a relationship between the value of the voltage that is applied to the MEA 110, and the current value Ip3 that is detected at time t3 after application of the DC voltage. The abscissa axis represents voltage value and the ordinate axis represents current value. The straight line in FIG. 8 is an approximation straight line that is calculated from points other than points that belong to a range D1 having a comparatively high voltage value.

In a case where the value of the voltage applied to the MEA 110 is small, as shown in FIG. 8, the detected current value stands in a substantially proportional relationship to the value of applied voltage, similarly to the approximation straight line L1. Depending on the characteristics of the MEA 110, in some instances the detected current value does not stand in a proportional relationship with the applied voltage, as in the range D1, if the value of the voltage that is applied to the MEA 110 is large. As a result, variability across samples in the current value detected from MEAs 110 may be substantial if the value of the voltage that is applied to the MEAs 110 is large. Therefore, the second voltage value V2 that is applied to the MEA 110 during the second period AT2 is preferably not excessive, and is preferably not greater than 0.5 V.

In the inspection method of the fuel cell 100 of the example, the current that flows upon application of DC voltage to the MEA 110 should be detected at a time where the current takes on a steady-state current value, as explained above. Preferably, therefore, the length of the first period AT1 in which the first voltage value V1 is applied ranges from 0.5 seconds to 2.5 seconds. In such a case, the deviation amount between the current value Ip2 and the current value Ip3 is small, the inspection time of the occurrence or absence of leaks in the MEA 110 is shortened, and high-precision inspection, with few reading errors, is made possible. Accordingly, the inspection method of the fuel cell 100 of the example allows inspecting the MEA 110 in a short time and with high precision.

In the inspection method of the fuel cell 100 of the example, the current that flows upon application of DC voltage to the MEA 110 should be detected at a time where the current takes on a steady-state current value. Accordingly, the value obtained by multiplying the length of the first period AT1 in which DC voltage having the first voltage value V1 is applied to the MEA 110, and the coefficient Cv that is obtained by dividing the first voltage value V1 by the second voltage value V2, ranges preferably from 0.4 to 4.0. In such a case, the deviation amount between the current value Ip2 and the current value Ip3 is small, the inspection time of the occurrence or absence of leaks in the MEA 110 is shortened, and high-precision inspection, with few reading errors, is made possible. Accordingly, the inspection method of the fuel cell 100 of the example allows inspecting the MEA 110 in a short time and with high precision.

In the inspection method of the fuel cell 100 of the example, the current value detected upon application of DC voltage to the MEA 110 should exhibit little variability across samples. Accordingly, the second voltage value V2 is preferably not greater than 0.5 volts. In such a case, the value of the voltage that is applied to the MEA 110 and the detected current value stand in a substantial proportional relationship, and hence variability across samples of the MEA 110 can be reduced. As a result, the inspection method of the fuel cell 100 of the example allows inspecting the MEA 110 in a short time and with reduced variability across samples.

B. Variations:

The invention is not limited to the above-described examples and embodiments, and may be embodied in various ways without departing from the scope of the invention. For instance, the invention may accommodate the following variations.

B1. Variation 1:

In the inspection method of the example above, the specific numerical values of the first voltage value V1 and the second voltage value V2 are exemplary in nature, and the first voltage value V1 and the second voltage value V2 are not limited to these numerical values. Likewise, the length of the first period AT1 and the second period AT2 is not limited to the numerical values in the example above. The same is true of time t1, time t2 and time t3.

B2. Variation 2:

The configuration of the fuel cell 100 in the inspection method of the example is merely exemplary in nature, and can accommodate various modifications. In the inspection method of the example above, for instance, the MEA 110 is used as the power generation element to be inspected. However, the power generation element may include the anode-side diffusion layer 124 and the cathode-side diffusion layer 122 in addition to the MEA 110, or may be made up of a plurality of MEAs 110. The power generation element may lack the anode-side gas flow path layer 134 and/or the cathode-side gas flow path layer 132.

In the inspection method of the example above, the electrolyte membrane 112 to be inspected, as well as the anode 116 and the cathode 114 have the same surface area in the surface direction, but the respective surface areas may be dissimilar. For instance, the surface area of the anode 116 may be greater than the surface area of the electrolyte membrane 112, and the surface of the cathode 114 may be smaller than the surface area of the electrolyte membrane 112.

In the inspection method of the example above, there is determined the occurrence or absence of leaks in a polymer electrolyte fuel cell, but the invention can be used also for inspection that involves determining the occurrence or absence of leaks in other types of fuel cell (for instance, direct methanol fuel cells, or phosphoric acid fuel cells).

B3. Variation 3:

In the inspection method of the fuel cell 100 of the example above, the first voltage value V I that is applied to the MEA 110 in the first period AT1 and the second voltage value V2 that is applied during the second period AT2 are constant voltage values, but that need not be the case. For instance, the first voltage value V1 may be a non-constant voltage value such that the voltage value rises gradually. Regarding the second voltage value V2, it is sufficient that the detected current value Ip2 be a steady-state current value. Therefore, the second voltage value V2 is not limited to application of a constant DC voltage during the second period AT2. In a case where the first voltage value V1 and the second voltage value V2 and are not constant, it is sufficient that the value of the voltage applied at time t2, when the current value Ip2 is detected in the second period AT2, be lower than the largest voltage value during the first voltage value V1.

In the inspection method of the example above, the first period AT1 starts at the same time that DC voltage starts being applied to the MEA 110, and the second period AT2 starts at the same time that the first period AT1 ends, but that need not be the case. For instance, a voltage value different from the first voltage value V1 may be applied to the MEA 110 before the start of the first period AT1. Also, some process may be included between the first period AT1 and the second period AT2, and hence the second period AT2 need not start at the same time that the first period AT1 ends. Preferably, however, the first period AT1 starts at the same time that voltage starts being applied to the MEA 110, and the second period AT2 starts at the same time that the first period AT1 ends, since inspection time of the MEA 110 can be shortened in such a case.

B4. Variation 4:

The constituent elements in the embodiments, examples and variations above can be appropriately omitted and/or combined with each other.

What is claimed is:

1. A fuel cell inspection method, comprising:
applying DC voltage of a first voltage value, in a first period, to a power generation element that includes an electrolyte membrane, an anode-side catalyst layer disposed on one side of the electrolyte membrane, and a cathode-side catalyst layer disposed on the other side of the electrolyte membrane; and
applying, to the power generation element, DC voltage of a second voltage value that is lower than the first voltage value, in a second period after the first period, and detecting a value of current flowing in the power generation element.

2. The inspection method according to claim 1, further comprising:
comparing the detected value of current with a predetermined threshold value.

3. The inspection method according to claim 2, wherein
it is determined whether a leak has occurred in the power generation element when the detected value of current is higher than the predetermined threshold value.

4. The inspection method according to claim 1, wherein
a length of the first period ranges from 0.5 seconds to 2.5 seconds.

5. The inspection method according to claim 1, wherein
a value obtained by multiplying a length of the first period by a coefficient that is calculated by dividing the first voltage value by the second voltage value ranges from 0.4 to 4.0.

6. The inspection method according to claim 1, wherein
the value of current is detected at a time where a predetermined time has elapsed from a start of the second period.

7. The inspection method according to claim 6, wherein
the predetermined time ranges from 1 second to 5 seconds.

8. The inspection method according to claim 1, wherein
the second voltage value is 0.5 volts or less.

9. The inspection method according to claim 1, wherein
the second period starts at the same time when the first period ends.

10. A fuel cell inspection device, comprising:
a voltage application unit that is configured to apply DC voltage of a first voltage value, in a first period, to a power generation element that includes an electrolyte membrane, an anode-side catalyst layer disposed on one side of the electrolyte membrane, and a cathode-side catalyst layer disposed on the other side of the electrolyte membrane, and that is configured to apply DC voltage of a second voltage value that is lower than the first voltage value, in a second period after the first period; and
a detection unit configured to detect a value of current flowing in the power generation element, in the second period.
